(19) United States
(12) Patent Application Publication
(10) Pub. No.: US 2015/0255411 A1
(43) Pub. Date: Sep. 10, 2015

(54) DIE-TO-DIE BONDING AND ASSOCIATED PACKAGE CONFIGURATIONS

(71) Applicants: Omkar G. Karhade, Chandler, AZ (US); Debendra Mallik, Chandler, AZ (US); Ravindranath V. Mahajan, Chandler, AZ (US); Amruthavalli P. Alur, Tempe, AZ (US)

(72) Inventors: Omkar G. Karhade, Chandler, AZ (US); Debendra Mallik, Chandler, AZ (US); Ravindranath V. Mahajan, Chandler, AZ (US); Amruthavalli P. Alur, Tempe, AZ (US)

(21) Appl. No.: 14/198,509

(22) Filed: Mar. 5, 2014

(51) Int. Cl. H01L 23/00; G06F 1/16; H01L 23/36

(52) U.S. Cl. CPC H01L 24/09; H01L 24/26; H01L 24/83; H01L 23/36; G06F 1/1686; G06F 1/1688; G06F 1/1694; G06F 1/1698; H01L 2224/80138; H01L 2224/80897; H01L 2224/8085; H01L 2224/0807

(57) ABSTRACT

Embodiments of the present disclosure are directed towards die-to-die bonding and associated integrated circuit (IC) package configurations. In one embodiment, a package assembly includes a package substrate having a solder resist layer disposed on a first side and a second side disposed opposite to the first side, a first die mounted on the first side and having an active side that is electrically coupled with the package substrate by one or more first die-level interconnects and a second die bonded with the active side of the first die using one or more second die-level interconnects, wherein at least a portion of the second die is disposed in a cavity that extends into the solder resist layer. Other embodiments may be described and/or claimed.

### FIELD

Embodiments of the present disclosure generally relate to the field of integrated circuits, and more particularly, to die-to-die bonding and associated integrated circuit (IC) package configurations.

### BACKGROUND

Smaller and lighter electronics devices with greater functionality are being developed in response to demand by customers for mobile computing devices such as, for example, smartphones and tablets. In some cases, multiple dies may be coupled together in a package. In order to create high bandwidth connections between the dies, very short interconnect lengths between the dies may be desirable. For example, face-to-face bonding of dies may provide a short electrical path between dies. However, face-to-face bonding is challenging in some configurations owing to a thickness of the dies. Current solutions may include, for example, separate bumping processes for face-to-face bond bumps to provide smaller stackup height relative to first-level interconnect (FLI) that couple the die to the package substrate, which may be costly. Another current solution may include thinning of one of the dies to a smaller thickness, which may make the thinned die more prone to damage and yield loss. For thinned dies that include magnetic core inductors, the performance of the inductors may be limited by thinning. Further, it may be desirable to reduce a z-height of face-to-face bonding configurations to provide a thinner package for emerging devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) package assembly, in accordance with some embodiments.

FIG. 2 schematically illustrates a cross-section side view of a face-to-face bonding configuration, in accordance with some embodiments.

FIG. 3 schematically illustrates a cross-section side view of another face-to-face bonding configuration, in accordance with some embodiments.

FIG. 4 schematically illustrates a flow diagram for a method of fabricating an IC package assembly, in accordance with some embodiments.

FIG. 5 schematically illustrates a computing device that includes an IC package assembly as described herein, in accordance with some embodiments.

FIG. 6 schematically illustrates a cross-section side view of another face-to-face bonding configuration, in accordance with some embodiments.

### DETAILED DESCRIPTION

Embodiments of the present disclosure describe die-to-die bonding and associated integrated circuit (IC) package configurations. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

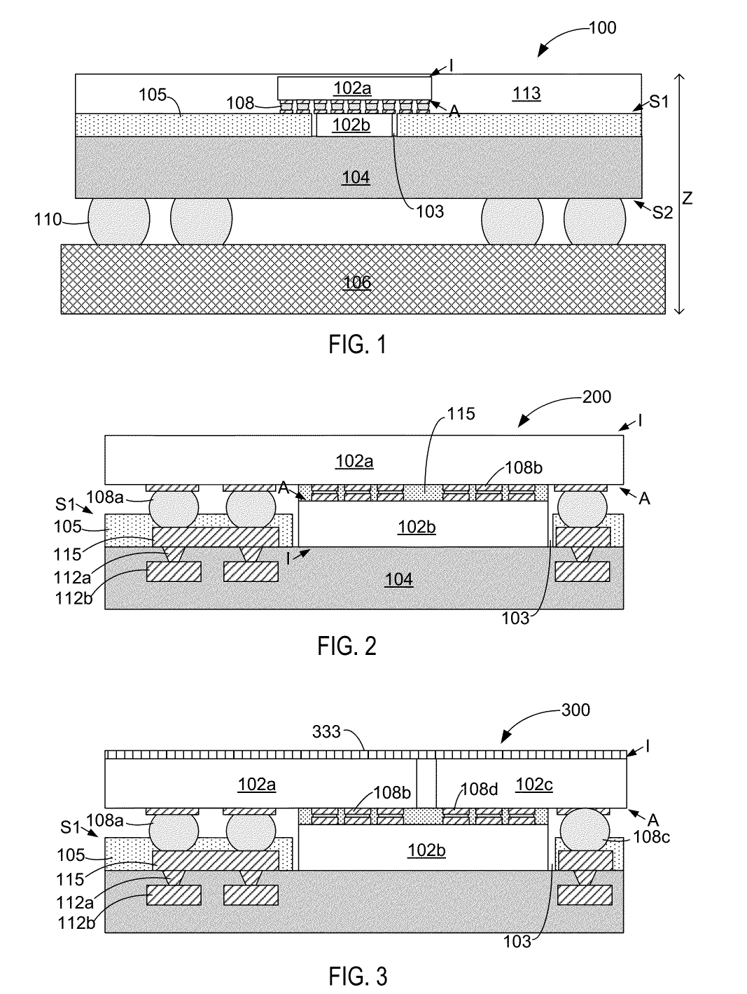

FIG. 1 schematically illustrates a cross-section side view of an example integrated circuit (IC) package assembly (hereinafter “package assembly 100”), in accordance with some embodiments. In some embodiments, the package assembly 100 may include two or more dies 102a, 102b electrically and/or physically coupled with a package substrate 104. In some embodiments, the package substrate 104 may be electrically coupled with a circuit board 106, as can be seen.

The dies 102a, 102b may each represent a discrete product made from a semiconductor material (e.g., silicon) using semiconductor fabrication techniques such as thin film deposition, lithography, etching and the like used in connection with forming CMOS devices. In some embodiments, each of the dies 102a, 102b may be, include, or be a part of a processor, memory, SoC or ASIC.

In some embodiments, the die 102a may be bonded to the die 102b in a face-to-face configuration using first-level interconnects (FLIs), which may be referred to as die-level interconnects 108 herein. The die-level interconnects 108 may include any of a variety of suitable structures including, for example, bumps, pillars, or another suitable structure. Die-level interconnects 108 may further couple the primary die 102a with the package substrate 104.

In some embodiments, the die-level interconnects 108 may be configured to route electrical signals between the dies 102a, 102b and/or other electrical devices (e.g., via the package substrate 104). The electrical signals may include, for example, input/output (I/O) signals and/or power/ground signals that are used in connection with operation of the dies 102a, 102b.

In some embodiments, the die 102a may represent a primary die and the die 102b may represent a secondary die that is bonded to the die 102a in a face-to-face configuration. For example, in some embodiments, the die 102a may represent a processor and the die 102b may represent memory, power management component (e.g., with capacitors and/or inductors, etc.), or bridge for routing electrical signals. The dies 102a, 102b may represent other suitable IC devices in other embodiments.

The die 102a may be directly coupled with the package substrate 104 in a flip-chip configuration, as depicted. In the flip-chip configuration, an active side, A, of the die 102a including active circuitry is attached to a surface of the package substrate 104 using die-level interconnects 108 that may also electrically couple the die 102a with the package substrate 104 (e.g., the die-level interconnects 108 may extend through the solder resist layer 105 as depicted in connection with FIGS. 2-3). The active side A of the die 102a may include, for example, transistor devices and an inactive side, I, may be disposed opposite to the active side A, as can be seen.

The die 102b may be disposed in a cavity 103 formed in a solder resist layer 105, as can be seen. In some embodiments, a backside of the die 102b may be coupled with the package substrate 104 within the cavity 103 using, for example, an adhesive or solder. The solder resist layer 105 may be an outermost layer on a first side S1 of the package substrate 104 of the package substrate 104. In some embodiments, the solder resist layer 105 may be composed of an electrically insulative polymer such as epoxy to provide protection of underlying components against environmental hazards such as, for example, oxidation. The solder resist layer 105 may be composed of other suitable materials in other embodiments.

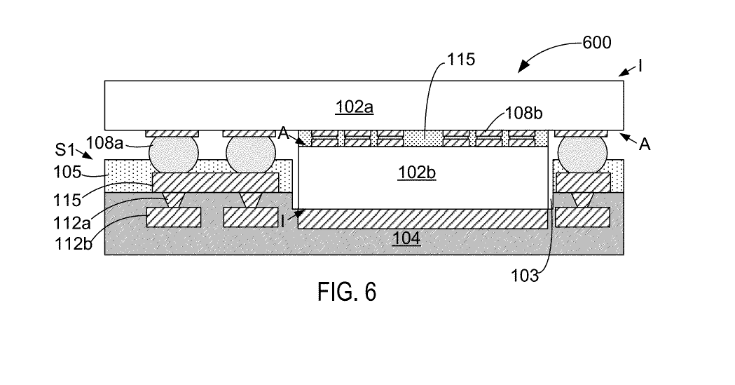

The cavity 103 in the solder resist layer 105 may accommodate a portion or the entire die 102b according to various embodiments. In some embodiments, the cavity 103 may not extend fully through the solder resist layer 105 or may extend into substrate layers (e.g., laminate layers such as build-up layers) underlying the solder resist layer 105 to accommodate a thickness of the die 102b. For example, in FIG. 6, the cavity 103 extends into a laminate layer of the package substrate 104 that is disposed beneath the solder resist layer 105 and at least a portion of the second die 102b is disposed in a portion of the cavity 103 that extends into the laminate layer. Placement of the die 102b within the cavity 103 may reduce a z-height, Z, of the package assembly 100 relative to a package assembly that does not utilize the space within the cavity 103.

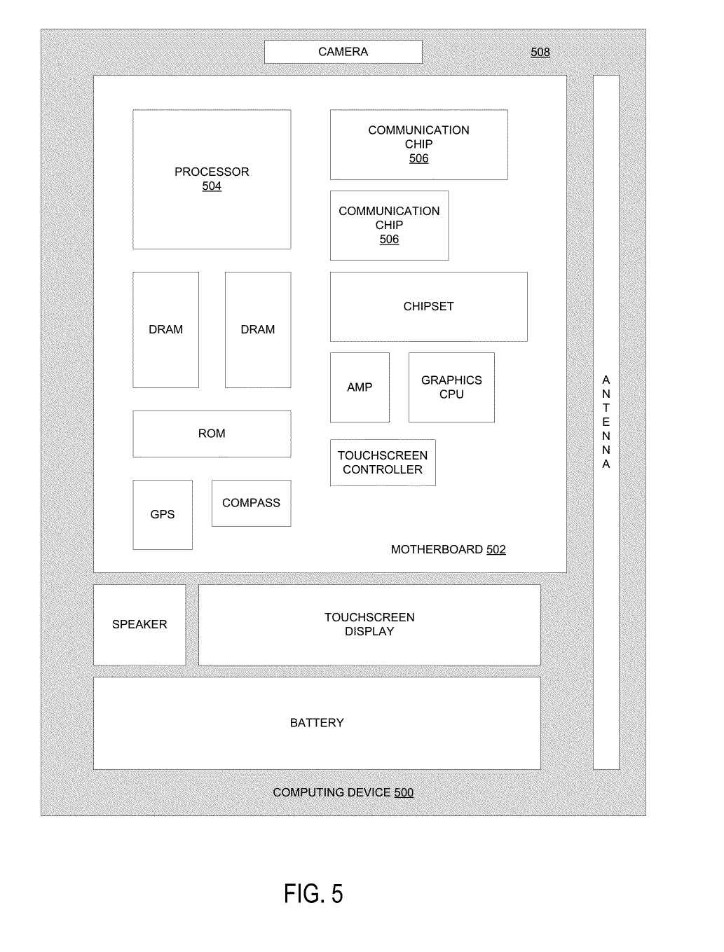

In some embodiments, the package substrate 104 is an epoxy-based laminate substrate having a core and/or build-up layers such as, for example, an Ajinomoto Build-up Film (ABF) substrate. The package substrate 104 may be a coreless substrate in some embodiments. In other embodiments, the package substrate 104 may be a circuit board such as, for example, a printed circuit board (PCB) formed using any suitable PCB technique. For example, in some embodiments, the package substrate 104 may serve as a motherboard (e.g., motherboard 502 of FIG. 5). The package substrate 104 may include other suitable types of substrates.

The package substrate 104 may include electrical routing features configured to route electrical signals to or from the die 102a and/or 102b. The electrical routing features may include, for example, contacts (e.g., pads 115 of FIG. 2) disposed on one or more surfaces of the package substrate 104 and/or internal routing features such as, for example, lines (e.g., lines 112b of FIG. 2) vias (e.g., vias 112a of FIG. 2) or other interconnect structures to route electrical signals through the package substrate 104. For example, in some embodiments, the package substrate 104 may include electrical routing features such as pads that are configured to receive the respective die-level interconnects 108 of the die 102a. In some embodiments, an electrically insulative material such as, for example, molding compound 113 or underfill material may encapsulate at least a portion of the package substrate 104, the dies 102a, 102b and/or die-level interconnects 108, as can be seen.

In some embodiments, the package substrate 104 may be coupled with circuit board 106. The circuit board 106 may be a printed circuit board (PCB) composed of an electrically insulative material such as an epoxy laminate. For example, the circuit board 106 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures (not shown) such as traces, trenches, vias may be formed through the electrically insulating layers to route the electrical signals of the die 102a and/or die 102b through the circuit board 106. The circuit board 106 may be composed of other suitable materials in other embodiments. In some embodiments, the circuit board 106 is a motherboard (e.g., motherboard 502 of FIG. 5).

Second level interconnects (SLIs), which may also be referred to as package-level interconnects, such as, for example, solder balls 110 may be coupled to one or more pads on a second side S2 of the package substrate 104 and/or on the circuit board 106 to form corresponding solder joints that are configured to further route the electrical signals between the package substrate 104 and an electrical device external to the package substrate 104 (e.g., the circuit board 106). Other suitable techniques to physically and/or electrically couple the package substrate 104 with the circuit board 106 may be used in other embodiments.

The package assembly 100 may include a wide variety of other suitable configurations in other embodiments including, for example, suitable combinations of flip-chip and/or wire-bonding configurations, interposers, multi-chip package configurations including system-in-package (SiP) and/or package-on-package (PoP) configurations. Other suitable techniques to route electrical signals between the dies 102a, 102b and other components of the package assembly 100 may be used in some embodiments. The package assembly 100 may include suitable combinations of the embodiments described herein.

FIG. 2 schematically illustrates a cross-section side view of a face-to-face bonding configuration 200, in accordance with some embodiments. According to various embodiments, the configuration 200 includes a die 102a mounted on the package substrate 104. The die 102a has an active side A that is electrically coupled with the package substrate 104 using one or more first die-level interconnects 108a. The active side A of the die 102a may be bonded with an active side A of the die 102b using one or more second die-level interconnects 108b.

In an embodiment where the die 102b is a power management die or bridge, the active side A of the die 102 may be bonded with a side of the die 102b that includes electrical contacts. In some embodiments, at least a portion of die 102b is disposed in a cavity 103 that extends into the solder resist layer 105. In some embodiments, a thickness of about 30 microns to 50 microns of the die 102b may be disposed within the cavity 103. Other thicknesses of the die 102b may be accommodated within the cavity 103 in other embodiments.

In some embodiments, the cavity 103 may extend into a laminate layer of the package substrate 104 that underlies the solder resist layer 105. For example, the cavity 103 may extend into layers of the package substrate 104 that include internal routing such as vias 112a and lines 112b to accommodate a thickness of the die 102b. In such embodiments, a metal feature (e.g., copper) such as a plate formed during fabrication of the vias 112a and/or lines 112b may be used to provide a stop layer for laser drilling of the material (e.g., epoxy laminate material) underlying the solder resist layer 105 and the die 102b may be coupled with the metal feature.

In some embodiments, multiple cavities may be formed in accordance with principles described in connection with cavity 103. For example, multiples dies (not shown) may be coupled with die 102a in a face-to-face manner as 102b or the configuration 200 may be repeated multiple times on a same package substrate 104.

In some embodiments, an underfill 115 such as an epoxy material may be disposed between the dies and the second die-level interconnects 108b. The underfill 115 may promote adhesion between the dies 102a, 102b and protect the second die-level interconnects 108b and/or active surfaces of the dies 102a, 102b.

FIG. 3 schematically illustrates a cross-section side view of another face-to-face bonding configuration 300, in accordance with some embodiments. In the configuration 300, multiples dies 102a, 102c are coupled with the die 102b disposed in the cavity 103. Die 102c may be mounted on the package substrate 104 and have an active side A that is electrically coupled with the package substrate 104 by one or more third die-level interconnects 108c. The active side A of the die 102c may be further bonded with the die 102b using one or more fourth die-level interconnects 108d. The cavity 103 may be disposed between the contacts (e.g., pads 115) that are configured to respectively couple with die-level interconnects 108a and 108c, as can be seen.

In some embodiments, the die 102b may be configured to route electrical signals between the die 102a, 102c. For example, in one embodiment, the dies 102a, 102c may be processors and the die 102b may serve as a silicon bridge between the dies 102a, 102c.

In some embodiments, an integrated heat spreader (IHS) 333 may be coupled with one or more of the dies 102a, 102c to facilitate heat removal from the dies. The IHS 333 may be coupled to an inactive side I of the dies 102a, 102c using, for example, a thermal adhesive.

Placement of die 102b within the cavity 103 may provide a variety of benefits. For example, such placement may allow use of a thicker die 102b in face-to-face bonding configurations (e.g., configurations 200 or 300 of FIG. 2 or 3), which may increase yields of the die 102b by avoiding a thinning process of the die. Additionally, in some embodiments, the die 102b may include magnetic core inductors, which may have a thickness that cannot be thinned without adversely affecting functionality. Further, formation of the cavity 103 may be performed using a same lithography process that may be used to form solder resist openings in the solder resist layer 105 for solderable material of the die-level interconnects (e.g., 108a, 108c), which may result in no additional significant cost to the process. Still further, a z-height of the package assembly may be reduced by placing the die 102b within the cavity 103. Embodiments disclosed herein may provide other benefits.

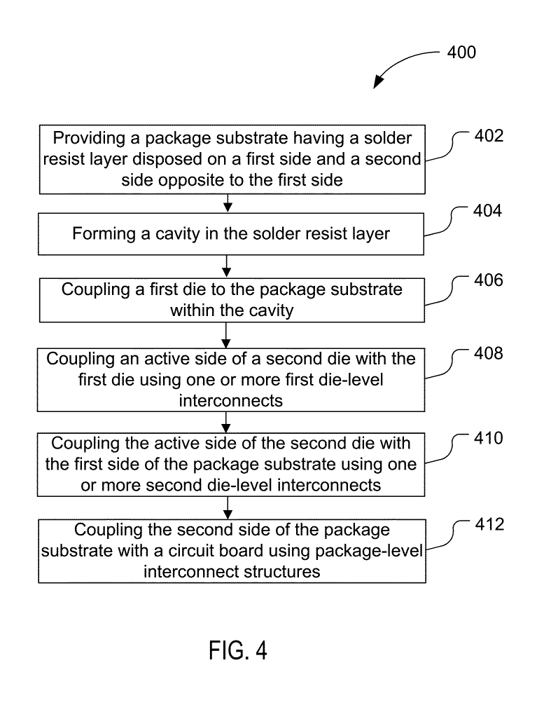

FIG. 4 schematically illustrates a flow diagram for a method 400 of fabricating an IC package assembly (e.g., package assembly 100 of FIG. 1), in accordance with some embodiments. The method 400 may comport with embodiments described in connection with FIGS. 1-3 and vice versa.

At 402, the method 400 may include providing a package substrate (e.g., package substrate 104 of FIGS. 1-3) having a solder resist layer (solder resist layer 105 of FIGS. 1-3) disposed on a first side (e.g., S1 of FIG. 1) and a second side (e.g., S2 of FIG. 1) opposite to the first side.

At 404, the method 400 may include forming a cavity (e.g., cavity 103 of FIGS. 1-3) in the solder resist layer. In some embodiments, material of the solder resist layer may be photodefinable and the cavity may be formed by removing material of the solder resist layer using a lithography process. In some embodiments, a same lithography process is used to simultaneously form the cavity and solder resist openings (SROs) for solderable material of die-level interconnects.

In embodiments where the cavity extends into material of the package substrate that underlies the solder resist layer, a metal feature (e.g., copper) such as a plate formed during fabrication of vias (e.g., vias 112a of FIGS. 2-3) and/or lines (e.g., lines 112b of FIGS. 2-3) may be used to provide a stop layer for laser drilling of the material (e.g., epoxy laminate material) underlying the solder resist layer.

At 406, the method 400 may include coupling a first die (e.g., die 102b) to the package substrate within the cavity. In some embodiments, coupling the first die to the package substrate may include aligning the first die within the cavity using contacts (e.g., pads 115 of FIGS. 2-3) corresponding with first die-level interconnects (e.g., first die-level interconnects 108a of FIG. 2 or 3) on the package substrate. In embodiments where the cavity extends into underlying material of the package substrate, the first die may be coupled with the metal feature that serves as a stop layer.

At 408, the method 400 may include coupling an active side of a second die (e.g., die 102a of FIG. 2 or FIG. 3) with the first die using one or more first die-level interconnects (e.g., first die-level interconnects 108a of FIG. 2 or 3). In some embodiments, the first die-level interconnects may be formed using a mass solder reflow or thermocompression bonding process.

At 410, the method 400 may include coupling the active side of the second die with the first side of the package substrate using one or more second die-level interconnects (e.g., second die-level interconnects 108b of FIG. 2 or 3). In some embodiments, the second die-level interconnects may be formed using a mass solder reflow or thermocompression bonding process.

In some embodiments where the second die-level interconnects include a solderable material, the solderable material may be deposited on the first die (e.g., die 102b of FIG. 2 may be bumped) while solderable material may not be deposited on the second die (e.g., die 102a of FIG. 2 may not be bumped), which may save cost and allow a smaller gap between the first die and the second die. In some embodiments

At 412, the method 400 may include coupling the second side of the package substrate with a circuit board (e.g., circuit board 106 of FIG. 1) using package-level interconnects (e.g., solder balls 110 of FIG. 1). Various operations are described as multiple discrete operations in turn, in a manner that is most helpful in understanding the claimed subject matter. However, the order of description should not be construed as to imply that these operations are necessarily order dependent. For example, in some embodiments, a process flow may include forming the cavity in the solder resist layer, followed by placing the first die face up in the cavity using an adhesive such as snap cure glue by aligning the first die to bumps on the package substrate, followed by simultaneously attaching the second die with the first die and the package substrate using mass solder reflow or thermocompression bonding. In other embodiments a process flow may include forming the cavity in the solder resist layer and attaching the first die and the second die together at wafer level or singulated level, followed by securing the dies further by depositing underfill between them, followed by attaching the combination of dies to the package substrate using mass solder reflow or thermocompression bonding. The method 400 may include other suitable variations of order.

Embodiments of the present disclosure may be implemented into a system using any suitable hardware and/or software to configure as desired. FIG. 5 schematically illustrates a computing device 500 that includes an IC package assembly (e.g., package assembly 100 of FIG. 1) as described herein, in accordance with some embodiments. The computing device 500 may house a board such as motherboard 502 (e.g., in housing 508). The motherboard 502 may include a number of components, including but not limited to a processor 504 and at least one communication chip 506. The processor 504 may be physically and electrically coupled to the motherboard 502. In some implementations, the at least one communication chip 506 may also be physically and electrically coupled to the motherboard 502. In further implementations, the communication chip 506 may be part of the processor 504.

Depending on its applications, computing device 400 may include other components that may or may not be physically and electrically coupled to the motherboard 502. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 506 may enable wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 506 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 506 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 506 may operate in accordance with other wireless protocols in other embodiments.

The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 may be packaged in an IC package assembly (e.g., package assembly 100 of FIG. 1) as described herein. For example, the circuit board 106 of FIG. 1 may be a motherboard 502 and the processor 504 may be a die 102a or 102c bonded with die 102b and mounted on a package substrate 104 of FIG. 1. The package substrate 104 and the motherboard 502 may be coupled together using package-level interconnects such as solder balls 110. Other suitable configurations may be implemented in accordance with embodiments described herein. The term “processor” may refer to any device or portion of a device that processes electronic data from registers and/or memory to transform that electronic data into other electronic data that may be stored in registers and/or memory.

The communication chip 506 may also include a die that may be packaged in an IC package assembly (e.g., package assembly 100 of FIG. 1) as described herein. In further implementations, another component (e.g., memory device or other integrated circuit device) housed within the computing device 500 may include a die that may be packaged in an IC package assembly (e.g., package assembly 100 of FIG. 1) as described herein.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 500 may be a mobile computing device in some embodiments. In further implementations, the computing device 500 may be any other electronic device that processes data.

### EXAMPLES

According to various embodiments, the present disclosure describes an apparatus (e.g., a package assembly). Example 1 of a package assembly may include a package substrate having a solder resist layer disposed on a first side and a second side disposed opposite to the first side, a first die mounted on the first side and having an active side that is electrically coupled with the package substrate by one or more first die-level interconnects and a second die bonded with the active side of the first die using one or more second die-level interconnects, wherein at least a portion of the second die is disposed in a cavity that extends into the solder resist layer. Example 2 may include the package assembly of Example 1, wherein the cavity extends into a laminate layer of the package substrate that is disposed beneath the solder resist layer and at least a portion of the second die is disposed in a portion of the cavity that extends into the laminate layer. Example 3 may include the package assembly of Example 1, further comprising a third die mounted on the first side of the package substrate and having an active side that is electrically coupled with the package substrate by one or more third die-level interconnects, wherein the second die is bonded with the active side of the third die by one or more fourth die-level interconnects. Example 4 may include the package assembly of Example 3, wherein the second die is configured to route electrical signals between the first die and the third die. Example 5 may include the package assembly of Example 1, wherein the cavity is a first cavity, the package assembly further comprising a second cavity formed in the solder resist layer, wherein at least a portion of a third die is disposed in the second cavity. Example 6 may include the package assembly of any of Examples 1-5, further comprising an integrated heat spreader (IHS) coupled with an inactive side of the first die and an epoxy material disposed between the first die and the second die. Example 7 may include the package assembly of any of Examples 1-5, wherein a thickness of 30 microns to 50 microns of the second die is disposed in the cavity. Example 8 may include the package assembly of any of Examples 1-5, wherein the first die is a processor and the second die is memory or a power management component. Example 9 may include the package assembly of Example 8, wherein the second die is a power management component having magnetic core inductors. Example 10 may include the package assembly of any of Examples 1-5, further comprising package-level interconnects disposed on the second side of the package substrate and configured to route electrical signals between the first die and an electrical device external to the package substrate.

According to various embodiments, the present disclosure describes another apparatus (e.g., a package substrate). Example 11 of a package substrate may include a solder resist layer disposed on a first side and a second side disposed opposite to the first side, contacts disposed on the first side and configured to couple with die-level interconnects disposed on an active side of a first die and a cavity that extends into the solder resist layer, the cavity being configured to accommodate at least a portion of a second die when the second die is bonded with the active side of the first die. Example 12 may include the package substrate of Example 11, wherein the cavity extends into a laminate layer of the package substrate that is disposed beneath the solder resist layer. Example 13 may include the package substrate of any of Examples 11-12, wherein the contacts are first contacts, the package substrate further comprising second contacts disposed on the first side and configured to couple with die-level interconnects disposed on an active side of a third die, wherein the cavity is disposed between the first contacts and the third contacts.

According to various embodiments, the present disclosure describes a method. Example 14 of a method may include providing a package substrate having a solder resist layer disposed on a first side and a second side disposed opposite to the first side, forming a cavity in the solder resist layer, coupling a first die to the package substrate within the cavity, coupling an active side of a second die with the first die using one or more first die-level interconnects and coupling the active side of the second die with the first side of the package substrate using one or more second die-level interconnects. Example 15 may include the method of Example 14, wherein forming the cavity comprises removing material of the solder resist layer using a lithography process. Example 16 may include the method of any of Examples 14-15, wherein coupling the active side of the second die with the first die and coupling the active side of the second die with the first side of the package substrate is simultaneously performed using a single thermal process and coupling the first die to the package substrate occurs prior to coupling the active side of the second die with the first die. Example 17 may include the method of Example 16, wherein coupling the first die to the package substrate comprises aligning the first die within the cavity using contacts of the package substrate corresponding with the second die-level interconnects as a reference for alignment and attaching the first die within the cavity using an adhesive. Example 18 may include the method of Example 14, wherein coupling the active side of the second die with the first die is performed prior to coupling the first die to the package substrate within the cavity and coupling the active side of the second die with the first side of the package substrate is performed subsequent to coupling the active side of the second die with the first die.

According to various embodiments, the present disclosure describes a system (e.g., a computing device). Example 19 of a computing device may include a circuit board and a package assembly coupled with the circuit board, the package assembly including a package substrate having a solder resist layer disposed on a first side and a second side disposed opposite to the first side, a first die mounted on the first side and having an active side that is electrically coupled with the package substrate by one or more first die-level interconnects, a second die bonded with the active side of the first die using one or more second die-level interconnects, wherein at least a portion of the second die is disposed in a cavity that extends into the solder resist layer. Example 20 may include the computing device of Example 19, wherein the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A package assembly comprising:
a package substrate having a solder resist layer disposed on a first side and a second side disposed opposite to the first side;
a first die mounted on the first side and having an active side that is electrically coupled with the package substrate by one or more first die-level interconnects; and
a second die bonded with the active side of the first die using one or more second die-level interconnects, wherein at least a portion of the second die is disposed in a cavity that extends into the solder resist layer.

2. The package assembly of claim 1, wherein:
the cavity extends into a laminate layer of the package substrate that is disposed beneath the solder resist layer; and
at least a portion of the second die is disposed in a portion of the cavity that extends into the laminate layer.

3. The package assembly of claim 1, further comprising:
a third die mounted on the first side of the package substrate and having an active side that is electrically coupled with the package substrate by one or more third die-level interconnects, wherein the second die is bonded with the active side of the third die by one or more fourth die-level interconnects.

4. The package assembly of claim 3, wherein the second die is configured to route electrical signals between the first die and the third die.

5. The package assembly of claim 1, wherein the cavity is a first cavity, the package assembly further comprising:
a second cavity formed in the solder resist layer, wherein at least a portion of a third die is disposed in the second cavity.

6. The package assembly of claim 1, further comprising:
an integrated heat spreader (IHS) coupled with an inactive side of the first die; and
an epoxy material disposed between the first die and the second die.

7. The package assembly of claim 1, wherein a thickness of 30 microns to 50 microns of the second die is disposed in the cavity.

8. The package assembly of claim 1, wherein the first die is a processor and the second die is memory or a power management component.

9. The package assembly of claim 8, wherein the second die is a power management component having magnetic core inductors.

10. The package assembly of claim 1, further comprising:
package-level interconnects disposed on the second side of the package substrate and configured to route electrical signals between the first die and an electrical device external to the package substrate.

11. A package substrate comprising:
a solder resist layer disposed on a first side and a second side disposed opposite to the first side;
contacts disposed on the first side and configured to couple with die-level interconnects disposed on an active side of a first die; and
a cavity that extends into the solder resist layer, the cavity being configured to accommodate at least a portion of a second die when the second die is bonded with the active side of the first die.

12. The package substrate of claim 11, wherein:
the cavity extends into a laminate layer of the package substrate that is disposed beneath the solder resist layer.

13. The package substrate of claim 11, wherein the contacts are first contacts, the package substrate further comprising:
second contacts disposed on the first side and configured to couple with die-level interconnects disposed on an active side of a third die, wherein the cavity is disposed between the first contacts and the third contacts.

14. A method comprising:
providing a package substrate having a solder resist layer disposed on a first side and a second side disposed opposite to the first side;
forming a cavity in the solder resist layer;
coupling a first die to the package substrate within the cavity;
coupling an active side of a second die with the first die using one or more first die-level interconnects; and
coupling the active side of the second die with the first side of the package substrate using one or more second die-level interconnects.

15. The method of claim 14, wherein forming the cavity comprises removing material of the solder resist layer using a lithography process.

16. The method of claim 14, wherein:
coupling the active side of the second die with the first die and coupling the active side of the second die with the first side of the package substrate is simultaneously performed using a single thermal process; and
coupling the first die to the package substrate occurs prior to coupling the active side of the second die with the first die.

17. The method of claim 16, wherein coupling the first die to the package substrate comprises:
aligning the first die within the cavity using contacts of the package substrate corresponding with the second die-level interconnects as a reference for alignment; and
attaching the first die within the cavity using an adhesive.

18. The method of claim 14, wherein:
coupling the active side of the second die with the first die is performed prior to coupling the first die to the package substrate within the cavity; and
coupling the active side of the second die with the first side of the package substrate is performed subsequent to coupling the active side of the second die with the first die.

19. A computing device, comprising:
a circuit board; and
a package assembly coupled with the circuit board, the package assembly including
a package substrate having a solder resist layer disposed on a first side and a second side disposed opposite to the first side;
a first die mounted on the first side and having an active side that is electrically coupled with the package substrate by one or more first die-level interconnects;
a second die bonded with the active side of the first die using one or more second die-level interconnects, wherein at least a portion of the second die is disposed in a cavity that extends into the solder resist layer.

20. The computing device of claim 19, wherein:
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
